(19) United States
(12) Patent Application Publication
(10) Pub. No.: US 2015/0276837 A1
(43) Pub. Date: Oct. 1, 2015

(54) ELECTRONIC DEVICE AND ANTENNA STATE DETERMINING METHOD OF THE ELECTRONIC DEVICE

(71) Applicant: Samsung Electronics Co., Ltd., Gyeonggi-do (KR)

(72) Inventors: Tae-Il KIM, Gyeonggi-do (KR); Dae Chul KANG, Gyeonggi-do (KR); Hyu Myung JEON, Gyeonggi-do (KR)

(73) Assignee: Samsung Electronics Co., Ltd.

(21) Appl. No.: 14/674,844

(22) Filed: Mar. 31, 2015

(30) Foreign Application Priority Data
Mar. 31, 2014 (KR) 10-2014-0037748

(51) Int. Cl. G01R 29/10

(52) U.S. Cl. CPC G01R 29/10

(57) ABSTRACT

An electronic device, an antenna state determining method, and a non-transitory computer readable recording medium. The electronic device includes an antenna configured to be extractable or detachable, an information collecting unit configured to collect information on a signal received via the antenna, and a determination unit configured to determine insertion, extraction, attachment, or detachment of the antenna by using the collected information. The method includes collecting information on a signal received via an extractable or detachable antenna; and determining insertion, extraction, attachment, or detachment of the antenna by using the collected information. The non-transitory computer readable recording medium having a program recorded thereon, which, when executed by a computer, performs a method including collecting information on a signal received via an extractable or detachable antenna; and determining insertion, extraction, attachment, or detachment of the antenna by using the collected information.

### PRIORITY

This application claims priority under 35 U.S.C. §119(a) to a Korean Patent Application filed Mar. 31, 2014 in the Korean Intellectual Property Office and assigned Serial No. 10-2014-0037748, the entire contents of which are incorporated herein by reference.

### BACKGROUND

1. Field of the Invention

The present invention relates generally to an electronic device capable of determining an antenna state thereof and a method of determining an antenna state of the electronic device, and more particularly, to an electronic device capable of determining whether an antenna is inserted or extracted via software.

2. Background of the Invention

As electronic technology is developed, electronic devices such as smart phones, tablet Personal Computers (PCs), and navigation devices have become popular. These electronic devices typically include antennas for wireless communication. An antenna mounted in an electronic device may be designed to have various frequency bands according to the type of wireless communication technology. Alternatively, an electronic device may include a plurality of antennas in some cases.

An antenna receiving a low frequency signal (e.g., a Digital Multimedia Broadcasting (DMB) or a Radio Frequency (RF) signal) is required to be relatively longer than one receiving a high frequency signal (e.g., a Wireless Fidelity (Wi-Fi) or Wideband Code Division Multiple Access (WCDMA) signal). Accordingly, an electronic device receiving a low frequency signal may include a separate extractable antenna for receiving the low frequency signal in addition to a fully embedded-type antenna for a WCDMA or Wi-Fi service.

In order to determine whether an antenna is inserted or extracted, an electronic device including an extractable antenna uses a hardware component that allows a circuit (e.g., a circuit for detecting an impedance change) to operate as a switch when the antenna is inserted or extracted. In other words, whether an antenna is inserted or extracted is determined according to physical movement of the antenna.

When a hardware component is used for determining whether an antenna is inserted or extracted, frequent use may cause a malfunction. In addition, space is required to include a switch, and cost increases due to the component.

### SUMMARY

The present invention has been made to address the above-mentioned problems and disadvantages, and to provide the advantages described below. Accordingly, an aspect of the present invention provides an electronic device capable of determining whether an antenna is inserted or extracted in a software manner without addition of a hardware component that operates as a switch, and an antenna state determining method of the electronic device.

According to an aspect of the present invention, an electronic device is provided. The electronic device includes an antenna configured to be extractable or detachable; an information collecting unit configured to collect information on a signal received via the antenna; and a determination unit configured to determine insertion, extraction, attachment, or detachment of the antenna by using the collected information.

According to another aspect of the present invention, an antenna state determining method of an electronic device is provided. The method includes collecting information on a signal received via an extractable or detachable antenna; and determining insertion, extraction, attachment, or detachment of the antenna by using the collected information.

According to another aspect of the present invention, a non-transitory computer readable recording medium having a program recorded thereon, which, when executed by a computer, performs a method. The method includes collecting information on a signal received via an extractable or detachable antenna; and determining insertion, extraction, attachment, or detachment of the antenna by using the collected information.

### BRIEF DESCRIPTION OF THE DRAWINGS

The above and other aspects, features, and advantages of the present invention will be more apparent from the following detailed description, taken in conjunction with the accompanying drawings, in which:

FIG. 1 illustrates a network environment including an electronic device according to an embodiment of the present invention;

FIG. 2 illustrates a configuration of a control module according to an embodiment of the present invention;

FIGS. 3A and 3B illustrate display screens according to an embodiment of the present invention; and

FIG. 4 is a flowchart of an antenna state determining method of an electronic device according to an embodiment of the present invention.

### DETAILED DESCRIPTION OF EMBODIMENTS OF THE PRESENT INVENTION

Hereinafter, the present invention is described with reference to the accompanying drawings. The present invention may be variously modified and may include various embodiments. While, embodiments of the present invention are illustrated in the drawings and detailed descriptions related thereto are provided below, it should be understood that the embodiments are not intended to limit the present invention, but rather the present invention is meant to cover all modifications, equivalents, and alternatives which are included within the spirit and scope of the present invention. Like reference numerals refer to like elements.

The terms “include,” “comprise,” “including,” and “comprising” used herein indicate disclosed functions, operations, or existence of elements but do not exclude other functions, operations or elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

The meaning of the term “or” used herein includes any combination of the words connected by the term “or.” For example, the expression “A or B” may indicate A, B, or both A and B.

The terms such as “first,” “second,” and the like used herein may refer to various elements of various embodiments of the present invention, but do not limit the elements. For example, such terms do not limit the order and/or priority of the elements. Furthermore, such terms may be used to distinguish one element from another element. For example, “a first user device” and “a second user device” indicate different user devices. For instance, without departing from the scope of the present invention, a first element may be named as a second element, and similarly, a second element may be named as a first element.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is not for limiting the present invention but for describing an embodiment of the present invention. The terms of a singular form may include plural forms unless otherwise specified.

Unless otherwise defined, the terms used herein, including technical or scientific terms, have the same meanings as understood by those skilled in the art. The general terms used herein should be interpreted according to the definitions in the dictionary or in the context and should not be interpreted as an excessively contracted meaning.

An electronic device according to the present invention includes a communication function. For example, electronic devices may include at least one of smartphones, tablet Personal Computers (PCs), mobile phones, video telephones, electronic book readers, desktop PCs, laptop PCs, network computers, Personal Digital Assistants (PDAs), Portable Multimedia Players (PMPs), Moving Picture Experts Group Audio Layer 3 (MP3) players, mobile medical devices, cameras, wearable devices (e.g., Head-Mounted-Devices (HMDs) such as electronic glasses), electronic apparel, electronic bracelets, electronic necklaces, electronic appcessories, electronic tattoos, and smart watches.

According to an embodiment of the present invention, electronic devices may be smart home appliances having communication functions. The smart home appliances may include at least one of, for example, TVs, Digital Video Disc (DVD) players, audio, refrigerators, air conditioners, cleaners, ovens, microwave ovens, washing machines, air cleaners, set-top boxes, TV boxes (e.g., Samsung HomeSync™, Apple TV™, or Google TV™), game consoles, electronic dictionaries, electronic keys, camcorders, and electronic picture frames.

According to an embodiment of the present invention, electronic devices may include at least one of medical devices (e.g., Magnetic Resonance Angiography (MRA), Magnetic Resonance Imaging (MRI), Computed Tomography (CT), scanners, and ultrasonic devices), navigation devices, Global Positioning System (GPS) receivers, Event Data Recorders (EDRs), Flight Data Recorders (FDRs), vehicle infotainment devices, electronic equipment for vessels (e.g., navigation systems and gyrocompasses), avionics, security devices, head units for vehicles, industrial or home robots, Automatic Teller Machines (ATMs), and Points of Sales (POSs).

According to an embodiment of the present invention, electronic devices may include at least one of parts of furniture or buildings/structures having communication functions, electronic boards, electronic signature receiving devices, projectors, and measuring instruments (e.g., water meters, electricity meters, gas meters, and wave meters). Electronic devices according to the present invention may be one or more combinations of the above-mentioned devices. Furthermore, electronic devices according to the present invention may be flexible devices. In addition, it would be obvious to those skilled in the art that electronic devices according to the present invention are not limited to the above-mentioned devices.

Hereinafter, electronic devices according to an embodiment of the present invention are described with reference to the accompanying drawings. The term “user” used herein may refer to a person who uses an electronic device or may refer to a device (e.g., an artificial electronic device) that uses an electronic device.

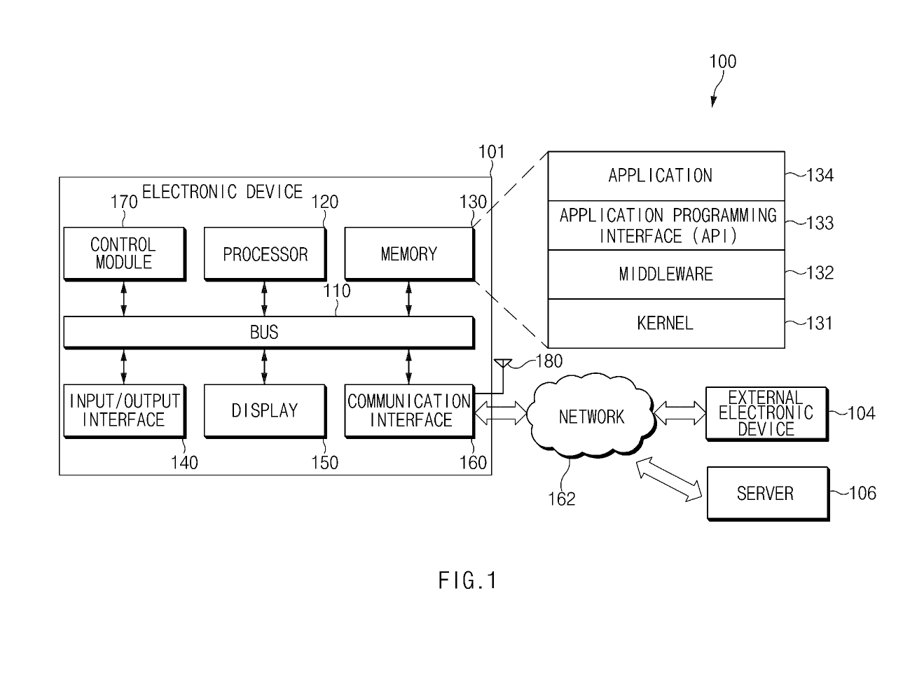

FIG. 1 illustrates a network environment 100 including an electronic device 101.

Referring to FIG. 1, the electronic device 101 includes a bus 110, a processor 120, a memory 130, and an input/output interface 140, a display 150, a communication interface 160, a control module 170 and an antenna 180.

The bus 110 is a circuit connecting the above-described elements to each other and delivering communications (e.g., a control message) between the above-described elements.

The processor 120 receives commands from other elements (e.g., the memory 130, the input/output interface 140, the display 150, the communication interface 160, or the control module 170), for example, via the bus 100, interprets the received commands, and performs operations or data processing according to the interpreted commands.

The memory 130 stores commands or data received from the processor 120 or other elements (e.g., the input/output interface 140, the display 150, the communication interface 160, or the control module 170), or created by the processor 120 or other elements. The memory 130 includes programming modules including, for example, a kernel 131, middleware 132, an Application Programming Interface (API) 133, and an application 134. Each of the above-described programming modules may be configured with software, firmware, hardware, or a combination of at least two of them.

The kernel 131 controls or manages system resources (e.g., the bus 110, the processor 120, or the memory 130, etc.) used for executing operations or functions implemented in the rest of the programming modules, for example, the middleware 132, the API 133, or the application 134. In addition, the kernel 131 provides an interface allowing the middleware 132, the API 133, or the application 134 to access, control, or manage an individual element of the electronic device 101.

The middleware 132 plays a relay role allowing the API 133 or the application 134 to communicate therewith and transmit and receive data. In addition, in relation to job requests received from the application 134, the middleware 132 perform control (e.g., scheduling or load balancing) for job requests by using a method of assigning a priority to at least one application among the application(s) 134, which is able to use the system resource (e.g., the bus 110, the processor 120 or the memory 130, etc.) of the electronic device 101.

The API 133 is an interface for controlling a function provided by the kernel 131 or the middleware 132, and includes at least one interface or function (e.g., a command) for, as an example, controlling a file, controlling a window, image processing or controlling a character.

According to an embodiment of the present invention, the application 134 includes a Short Message Service/Multimedia Messaging Service (SMS/MMS) application, an email application, a calendar application, an alarm application, a healthcare application (e.g., an application for measuring an exercise amount or a blood sugar level), or an environmental information application (e.g., an application providing atmospheric pressure, humidity, or temperature information). Additionally or alternatively, the application 134 may be an application related to information exchange between the electronic device 101 and an external electronic device (e.g., an external electronic device 104). The application related to the information exchange may include, for example, a notification relay application for delivering designated information to the external electronic device, or a device management application for managing the external electronic device.

For example, the notification delivery application may include a function of delivering, to the external electronic device, notification information created by other applications (e.g., the SMS/MMS application, an email application, a healthcare application or an environmental information application, etc.) of the electronic device 101. Additionally or alternatively, the notification delivery application may receive the notification information, for example, from the external device (e.g., the external electronic device 104) and provide it to a user. The device management application may manage (e.g., install, delete, or update), for example, functions (e.g., turning on/off the external electronic device (or a part of components) or adjustment of brightness (or resolution) of a display) for at least a part of the external electronic device (e.g., the external electronic device 104) communicating with the electronic device 101, applications operating in the external electronic device, or services (e.g., call service or messaging service) provided in the external electronic device.

According to an embodiment of the present invention, the application 134 includes an application designated according to attributes (e.g., a kind of electronic device) of the external electronic device (e.g., the external electronic device 104). For example, when the external electronic device is an MP3 player, the application 134 includes an application related to the playback of music. Similarly, in a case where the external electronic device is mobile medical equipment, the application 134 includes an application related to health management. According to an embodiment of the present invention, the application 134 includes at least one of an application designated in the electronic device 101 and an application received from the external electronic device (e.g., the server 106 or the external electronic device 104).

The input/output interface 140 delivers commands or data input from the user via an input/output device (e.g., a sensor, keyboard, or touch screen) to the processor 120, the memory 130, the communication interface 160 or the control module 170 via, for example, the bus 110. For example, the input/output interface 140 provides user touch data input via a touch screen to the processor 120. In addition, the input/output interface 140 outputs, via the input/output device (e.g., a speaker or display), commands or data received from the processor 120, the memory 130, the communication interface 160, or the control module 170 via, for example, the bus 110. For example, the input/output interface 140 outputs voice data processed via the processor 120 to the user via the speaker.

The display 150 displays various types of information (e.g., multimedia data or text data, etc.) to the user.

The communication interface 160 enables communication between the electronic device 101 and an external device (e.g., the external electronic device 104 or the server 106). For example, the communication interface 160 is connected to a network 162 via wireless or wired communication and communicates with the external electronic device. The wireless communication may include at least one wireless communication selected from, for example, Wireless Fidelity (Wi-Fi), Bluetooth (BT), Near Field Communication (NFC), GPS, or cellular communication (e.g., Long Term Evolution (LTE), LTE-Advanced (LTE-A), Code Division Multiple Access (CDMA), Wideband CDMA (WCDMA), Universal Mobile Telecommunications System (UMTS), Wireless Broadband (WiBro) or Global System for Mobile communications (GSM)). The wired communication may include at least one wired communication selected from, for example, Universal Serial Bus (USB), High Definition Multimedia Interface (HDMI), Recommended Standard (RS)-232, and Plain Old Telephone Service (POTS).

According to an embodiment of the present invention, the network 162 is a telecommunications network. The telecommunications network may include at least one telecommunications network selected from a computer network, the Internet, the Internet of things, or a telephone network. According to an embodiment of the present invention, a protocol (e.g., a transport layer protocol, a data link layer protocol, or a physical layer protocol, etc.) for communication between the electronic device 101 and the external electronic device may be supported by at least one programming module selected from the application 134, the API 133, the middleware 132, the kernel 131, and the communication interface 160.

The control module 170 processes at least a part of information obtained from other elements (e.g., the processor 120, the memory 130, the input/output interface 140, or the communication interface 160, etc.) and provides the processed result to the user in various ways. For example, the application control module 170 recognizes information on connection components prepared in the electronic device 101, stores the information on the connection components in the memory 130, and executes the application 134 on the basis of the information on the connection components.

According to an embodiment of the present invention, the antenna 180 receives a signal. For example, the antenna 180 may receive a DMB signal or a Radio Frequency (RF) signal (e.g., an Amplitude Modulation (AM) or a Frequency Modulation (FM) signal).

According to an embodiment of the present invention, the antenna 180 is implemented in an extractable type. For example, the antenna 180 is inserted into a space prepared in the electronic device 101. In the state where the antenna 180 is inserted, it is difficult to receive a signal. In addition, when it is necessary to receive a signal, the antenna 180 is extracted by the user. The antenna 180 may be implemented in a telescopic structure for reducing space required to insert the antenna.

According to an embodiment of the present invention, the communication interface 160 receives a signal using the antenna 180. The communication interface 160 is implemented with a Radio Frequency Integrated Circuit (RFIC). The RFIC allows a frequency of the received signal to be changed and a fixed frequency to be output. According to an embodiment of the present invention, the RFIC may include a Phase Locked Loop (PLL) block. The PLL block fixes an output frequency of a received signal.

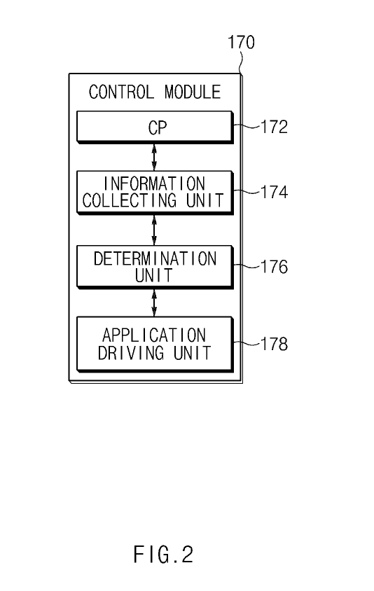

According to an embodiment of the present invention, the control module 170 determines whether the antenna 180 is inserted or extracted by using a signal received via the antenna 180. The control module 170 is described with reference to FIG. 2.

FIG. 2 illustrates a configuration of a control module according to an embodiment of the present invention.

Referring to FIG. 2, the control module 170 includes a communication processor (CP) 172, an information collecting unit 174, a determination unit 176, and an application driving unit 178.

According to an embodiment of the present invention, the CP 172 performs functions of managing data links and converting a communication protocol in communications between the electronic device 101 and other electronic devices connected via the network 162. The CP 172 processes signals input from the communication interface 160 and converts the processed signal into a signal of a reproducible signal in the electronic device 101. According to an embodiment of the present invention, the CP 172 includes a demodulator for demodulating a signal input from the communication interface 160.

According to an embodiment of the present invention, the information collecting unit 174 collects information on a received signal. The information collecting unit 174 collects at least one piece of information selected from whether a signal received via the antenna 180 is Phase Locked Loop (PLL) locked, a Received Signal Strength Indicator (RSSI), a Packet Error Rate (PER), a Bit Error Rate (BER), and a combination thereof.

According to an embodiment of the present invention, the information collecting unit 174 collects information on whether a signal from the communication interface 160 is PLL locked. The information collecting unit 174 collects information on the RSSI, PER, or BER from the CP 172. For example, the information collecting unit 174 collects information on the RSSI, PER, or BER from the demodulator included in the CP 172.

According to an embodiment of the present invention, the information collecting unit 174 collects information on a signal received via the antenna 180 in a set time interval. For example, the information collecting unit 174 collects information on a signal received in 3 second interval. The information collecting unit 174 may collect information in a state where the communication interface 160 or the CP 172 operates. According to an embodiment of the present invention, a power supply of the communication interface 160 or the CP 172 may be turned on/off according to an information collection period of the information collecting unit 174.

According to an embodiment of the present invention, the determination unit 176 determines insertion or extraction of the antenna 180 by using the information collected by the information collecting unit 174. According to an embodiment of the present invention, the determination unit 176 determines insertion or extraction of the antenna 180 by using at least one piece of information selected from an RSSI, whether PLL locked, a PER, a BER, and a combination thereof.

According to an embodiment of the present invention, when a signal received via the antenna 180 is PLL locked, the determination unit 176 determines that the antenna is extracted. According to an embodiment of the present invention, when the signal received via the antenna 180 is not PLL locked, the determination unit 176 determines that the antenna is inserted. For example, since a gain of the antenna 180 is very small when the antenna 180 is inserted, PLL locking is not possible in the PLL block. According to an embodiment of the present invention, when the antenna 180 is extracted, PLL locking may be conducted even in an area where an electric field is so weak that content may not be normally reproduced. The determination unit 176 determines insertion or extraction of the antenna 180 by identifying whether PLL locking is applied.

According to an embodiment of the present invention, the determination unit 176 determines that the antenna 180 is extracted when an RSSI of a signal is greater than or equal to a first set reference value. For example, when an RSSI of a signal is greater than or equal to −70 dBm, the determination unit 176 determines that the antenna 180 is extracted. According to an embodiment of the present invention, when an RSSI of a signal is less than a second set reference value, the determination unit 176 determines that the antenna 180 is inserted. For example, when an RSSI of the signal is less than −90 dBm, the determination unit 176 may determine that the antenna 180 is inserted. According to an embodiment of the present invention, the first or second reference value may be set identically or differently.

According to an embodiment of the present invention, when the PER or BER of a signal is less than a first set reference value, the determination unit 176 determines that the antenna 180 is extracted. For example, when the PER is less than 5%, the determination unit 176 determines that the antenna 180 is extracted. According to an embodiment of the present invention, when the PER or BER of the signal is greater than or equal to a second set reference value, the determination unit 176 determines that the antenna 180 is inserted. In another example, when the PER of the signal is greater than or to 10%, the determination unit 176 determines that the antenna 180 is inserted.

According to an embodiment of the present invention, the determination unit 176 compares previously collected information and currently collected information and calculates a variation of at least one piece of information selected from an RSSI, a PER, and a BER. For example, the determination unit 176 calculates differences from the previously collected information on the basis of the currently collected information and calculates the variation of at least one piece of information selected from an RSSI, a PER, a BER, and a combination thereof.

According to an embodiment of the present invention, the determination unit 176 determines the insertion or extraction of the antenna 180 by using at least one piece of information selected from an RSSI variation, a PER variation, a BER variation, and a combination thereof.

According to an embodiment of the present invention, when an RSSI increase of a signal is greater than or equal to a first set reference value, the determination unit 176 determines that the antenna 180 is extracted. For example, when the RSSI increase of the signal is greater than or equal to 20 dBm, the determination unit 176 determines that the antenna 180 is extracted. According to an embodiment of the present invention, when an RSSI decrease of the signal is greater than or equal to a second set reference value, the determination unit 176 determines that the antenna is inserted. For example, when an RSSI decrease is greater than or equal to 20 dBm, the determination unit 176 determines that the antenna is inserted.

According to an embodiment of the present invention, when a decrease of the PER or BER of a signal is greater than or equal to a first set reference value, the determination unit 176 determines that the antenna 180 is extracted. For example, when the PER decrease of the signal is greater than or equal to 5% (e.g. 1/20), the determination unit 176 determines that the antenna 180 is extracted. According to an embodiment of the present invention, when an increase of the PER or BER of a signal is greater than or equal to a second set reference value, the determination unit 176 determines that the antenna 180 is inserted. For example, when an increase of the PER of the signal is greater than or equal to 5% (e.g. 1/20), the determination unit 176 determines that the antenna 180 is inserted.

According to an embodiment of the present invention, the determination unit 176 determines insertion or extraction of the antenna 180 by using at least one piece of information selected from a PLL locking state, an RSSI, a BER, a PER, an RSSI variation, a BER variation, a PER variation, and a combination thereof. For example, when an RSSI is greater than or equal to a set reference value (e.g., −17 dBm), the state of a signal is PLL locked, a PER or a BER is less than a reference value (e.g., 5%), and an RSSI variation is greater than or equal to a reference value (e.g., 30 dBm), the antenna 180 is determined to be extracted.

According to an embodiment of the present invention, the determination unit 176 determines insertion or extraction of the antenna 180 via a combination of information (e.g., a PLL locking state, an RSSI, a BER, a PER, or variations thereof) collected by the information collecting unit 174 on the basis of an electric field intensity (e.g., strong electric field, weak electric field). For example, in a strong electric field interval (e.g., an interval where an RSSI ≧−60 dBm), a PLL locking is possible in a state where the antenna 180 is inserted. Under corresponding conditions, the determination unit 176 may determine the insertion or extraction of the antenna 180 by checking a PLL locking state, an RSSI variation, or a BER variation. In another example, in a medium/weak electric field (e.g., an interval where an RSSI <−60 dBm), the determination unit 176 determines the insertion or extraction of the antenna 180 on the basis of at least one piece of information selected from a PLL locking state, an RSSI variation, a BER variation, and a PER variation.

According to an embodiment of the present invention, the determination unit 176 sets at least one reference value of an RSSI, a PER, and a BER differently, according to a location of the electronic device 101. For example, the determination unit 176 sets at least one reference value of an RSSI, a PER, and a BER differently according to the location of the electronic device 101 by using at least one piece of information selected from current location information, quality information (e.g., an RSSI, a PER, or a PER) of a signal according to the location, which is pre-stored in the memory 130, and electric field intensity information according to the location. For example, for an RSSI reference value, the RSSI reference value is set relatively high in a location where signal quality is good, and the RSSI reference value is set relatively low in a location where the signal quality is bad.

According to an embodiment of the present invention, the determination unit 176 receives the current location information from a Global Position System (GPS), or the CP 172. For example, the CP 172 obtains the current location information by using a Wi-Fi, WCDMA, or LTE network.

According to an embodiment of the present invention, when the determination unit 176 determines that the antenna 180 is extracted, the application driving unit 178 drives a corresponding application. According to an embodiment of the present invention, when the determination unit 176 determines that the antenna 180 is extracted, the application driving unit 178 drives a broadcasting application.

According to an embodiment of the present invention, when a user's preferred channel is set in an automatically executed application, the application driving unit 178 searches for the set preferred channel together with the execution of the application and provides it to the user.

According to an embodiment of the present invention, as the antenna 180 is extracted, whether to automatically execute the application is set by the user. As describe above, when the antenna 180 is extracted in a state where the application is set to be automatically executed, the corresponding application is automatically executed. According to an embodiment of the present invention, in a state where the application is not set to be automatically executed, even though the antenna 180 is extracted, the application is not automatically executed. According to an embodiment of the present invention, in a state where the application is not set to be automatically executed, when the antennal 180 is extracted, a menu for executing an application (e.g., a broadcasting application or a radio player application) using a signal received via the antenna 180 is provided via the display 150.

According to an embodiment of the present invention, a user sets an application to be automatically driven as the antenna 180 is extracted. For example, when desiring to view a DMB broadcast as the antenna 180 is extracted, the user sets the DMB application to be executed. In another example, when desiring to listen to the radio as the antenna 180 is extracted, the user sets a radio player application to be executed.

According to an embodiment of the present invention, when the determination unit 176 determines that the antenna 180 is inserted, the application driving unit 178 terminates the application being executed. The terminated application may be an application identical to an application driven by the extraction of the antennal 180.

In an embodiment of the present invention, the information collecting unit 174, the determination unit 176, or the application driving unit 178 is described as being separately configured. However, at least one unit selected from the information collecting unit 174, the determination unit 176, and the application driving unit 178 may be implemented with one processor such as a System on Chip (SoC).

According to an embodiment of the present invention, the memory 130 stores an Operating System (OS) necessary for driving the electronic device 101, various applications or contents. According to an embodiment of the present invention, the display 150 displays video data output from the signal processing unit. For example, when the antenna 180 is extracted in a state where the application is set to not be automatically executed, the display 150 provides a menu for executing an application (e.g., a broadcasting application or a radio player application) using a signal received via the antenna 180.

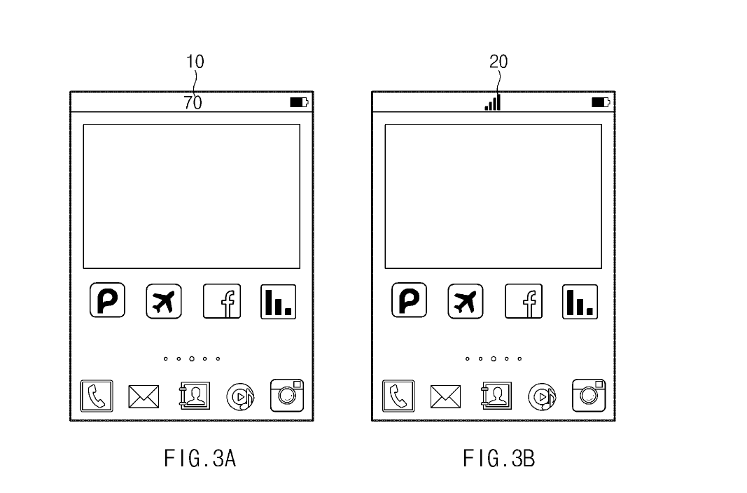

According to an embodiment of the present invention, the display 150 displays an object (or an indicator) representing strength of a signal received via the antenna 180. Details regarding this are described below with reference to FIGS. 3A and 3B.

FIGS. 3A and 3B illustrate display screens according to an embodiment of the present invention.

Referring to FIGS. 3A and 3B, the display 150 displays an object representing strength of a signal received via the antenna 180. For example, as in FIG. 3A, the display 150 displays a numeral 10 corresponding to the strength of a received signal. In another example, as show in FIG. 3B, the display 150 displays a graphic object 20 representing strength of a received signal. Referring to FIG. 3B, the graphic object includes a plurality of subdivided (or sub) objects and the number of the subdivided objects displayed may be determined according to the strength of the received signal. For example, when the strength of the received signal increases, the number of the displayed subdivided objects increases. When the strength of the received signal decreases, the number of the displayed subdivided objects decreases. In another example, the subdivided objects displayed according to the strength of the received signal includes subdivided objects corresponding to a broadcast application executed on the basis of the signal received via the antenna 180.

According to an embodiment of the present invention, when an application is set to be automatically driven upon extraction of the antenna 180, the display 150 displays an object representing the strength of the signal received via the antenna 180.

For example, when the electronic device 101 is located at a location where a signal is not normally received due to very weak signal strength or low quality, it may occur that the antenna 180 is not determined as extracted despite being extracted. In this situation, the user may intuitively know he/she is in an area where the broadcast application (e.g., DMB or radio) is not normally viewed.

According to an embodiment of the present invention, the input/output interface 140 receives a user command. According to an embodiment of the present invention, the input/output interface 140 receives a user command for setting whether to automatically drive an application when the antenna 180 is extracted. When the application is set to be automatically driven, the input/output interface 140 receives a user command for setting which application is to be automatically driven. The input/output interface 140 may receive a user command for setting a channel in the application to be automatically driven.

According to an embodiment of the present invention, the input/output interface 140 receives a user command for executing one of the applications included in a menu, when an application is not set to be automatically driven and the menu for executing an application is provided.

In the above-described embodiment of the present invention, the antenna 180 is implemented in an extractable type inside the electronic device 101. However, the antenna 180 may be implemented in a detachable type in the electronic device 101.

According to an embodiment of the present invention, the antenna 180 is implemented in an embedded type inside a detachable earphone of the electronic device 101. For example, when an ear phone is attached to the electronic device 101, a signal is received via the embedded antenna 180 inside the earphone. When the earphone is detached from the electronic device 101, the signal may not be received.

According to an embodiment of the present invention, even in a case where the antenna 180 is implemented in the detachable type, the rest of the elements of the electronic device 101 may operate in the same way as those described in relation to FIG. 1. For example, the determination unit 176 determines attachment or detachment of the antenna 180 by using information collected by the information collecting unit 174. According to an embodiment of the present invention, the application driving unit 178 drives a corresponding application, when the antenna 180 is determined as attached.

An electronic device 101 according to an embodiment of the present invention includes an extractable or detachable antenna 180, an information collecting unit 174 collecting information on a signal received via the antenna 180, and a determination unit 176 determining insertion, extraction, attachment, or detachment of the antenna 180 by using the collected information.

According to an embodiment of the present invention, the information collecting unit 174 collects at least one piece of information selected from whether a signal is PLL locked, an RSSI, a BER, a PER, and a combination thereof.

According to an embodiment of the present invention, when the signal is PLL locked, the determination unit 176 determines that the antenna 180 is extracted or attached.

According to an embodiment of the present invention, when an RSSI increase of a signal is greater than or equal to a set reference value, the determination unit 176 determines the antenna 180 is extracted or attached.

According to an embodiment of the present invention, when a PER or BER decrease of a signal is greater than or equal to a set reference value, the determination unit 176 determines that the antenna 180 is extracted or attached.

According to an embodiment of the present invention, the reference values may be differently set according to a location of the electronic device 101.

According to an embodiment of the present invention, the information collecting unit 174 collects information on a signal in a set time interval.

According to an embodiment of the present invention, a display 150 is further included which displays an object representing strength of a signal received via the antenna 181.

According to an embodiment of the present invention, an application driving unit 178 is further included which drives a corresponding application when the antenna 180 is determined as extracted or attached.

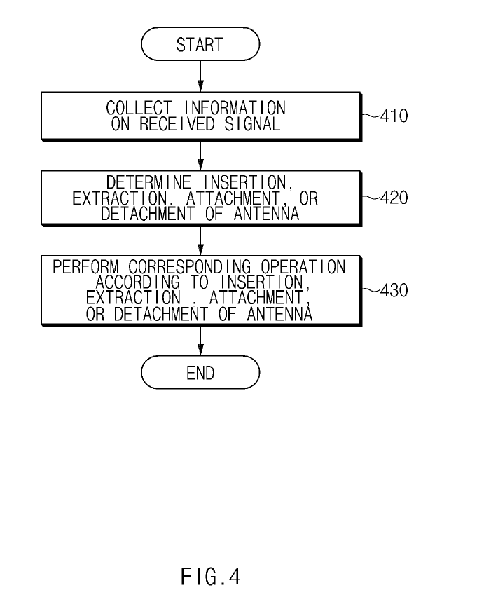

FIG. 4 is a flowchart of an antenna 180 state determining method of an electronic device 101 according to an embodiment of the present invention.

The flowchart of FIG. 4 includes operations processed in the electronic device 101 illustrated in FIG. 1. Therefore, even though omitted below, the content described above concerning the electronic device 101 illustrated in FIG. 1 may also be applied to the flow chart of FIG. 4.

Referring to FIG. 4, according to an embodiment of the present invention, in step 410, the electronic device 101 collects information on a signal received via an extractable or detachable antenna 180. According to an embodiment of the present invention, the electronic device 101 collects at least one piece of information selected from whether the received signal is PLL locked, the RSSI, the PER and the BER of the received signal. According to an embodiment of the present invention, the electronic device 101 collects information on the received signal in a set time interval.

According to an embodiment of the present invention, in step 420, whether the antenna 180 is extracted or detached is determined by using the collected information. According to an embodiment of the present invention, when the received signal is PLL locked, the electronic device 101 determines that the antenna 180 is extracted or attached. According to an embodiment of the present invention, when the received signal is not PLL locked, the electronic device 101 determines that the antenna 180 is inserted or detached.

According to an embodiment of the present invention, when the RSSI of the received signal is greater than or equal to a first set reference value, the electronic device 101 determines that the antenna 180 is extracted or attached. According to an embodiment of the present invention, when the RSSI of the received signal is less than a second set reference value, the electronic device 101 determines that the antenna 180 is inserted or detached.

According to an embodiment of the present invention, when the PER or BER of a received signal is less than a first set reference value, the electronic device 101 determines that the antenna 180 is extracted or attached. According to an embodiment of the present invention, when the PER or BER of a received signal is greater than or equal to a second set reference value, the electronic device 101 determines that the antenna 180 is inserted or detached.

According to an embodiment of the present invention, the electronic device 101 calculates the RSSI variation of a received signal. When an RSSI increase of the received signal is greater than or equal to a set first reference value, the electronic device 101 determines that the antenna 180 is extracted or attached. According to an embodiment of the present invention, when an RSSI decrease of the received signal is greater than or equal to a set second reference value, the electronic device 101 determines that the antenna 180 is inserted or detached.

According to an embodiment of the present invention, the electronic device 101 calculates a variation of the PER or BER of a received signal. When a PER or BER decrease of the received signal is greater than or equal to a first set reference value, the electronic device 101 determines that the antenna 180 is extracted or attached. According to an embodiment of the present invention, when a PER or BER increase of a received signal is greater than or equal to a second set reference value, the electronic device 101 determines that the antenna 180 is inserted or detached.

According to an embodiment of the present invention, the electronic device 101 collects current location information and sets reference values differently according to the location.

According to an embodiment of the present invention, in step 430, the electronic device 101 performs an operation correspond to insertion, extraction, attachment or detachment of the antenna 180. When the antenna 180 is determined as extracted or attached, the electronic device 101 drives a corresponding application. For example, the electronic device 101 may drive a broadcast viewing application. According to an embodiment of the present invention, the corresponding application may be set by the user.

According to an embodiment of the present invention, when the antenna 180 is determined as inserted or detached, the electronic device 101 terminates an application being executed. The terminated application may be the same application as an application driven by the extraction or attachment of the antenna 180.

According to an embodiment of the present invention, the electronic device 101 displays an object representing strength of the signal received via the antenna 180 on a display screen. For example, as described in relation to FIGS. 3A and 3B, the electronic device 101 may display a numeral 10 in proportion to the strength of a received signal. In another example, the electronic device 101 displays a graphic object 20 representing the strength of a signal. According to an embodiment of the present invention, the graphic object includes a plurality of subdivided objects, and the number of the subdivided objects displayed according to the strength of the received signal may be determined. For example, when the strength of the received signal increases, the number of the subdivided objects increases. When the strength of the received signal decreases, the number of the subdivided objects decreases.

According to an embodiment of the present invention, when an application is set to be automatically driven according to extraction of the antenna 180, the electronic device 101 displays an object representing the strength of the signal received via the antenna 180.

An antenna 180 state determining method of an electronic device 101 according to an embodiment of the present invention includes collecting information on a signal received via an extractable or detachable antenna 180 and determining insertion, extraction, attachment, or detachment of the antenna 180 by using the collected information.

According to an embodiment of the present invention, the operation of collecting information on a signal includes an operation of collecting at least one piece of information selected from whether the signal is PLL locked, a RSSI, a PER, a BER, and a combination thereof.

According to an embodiment of the present information, the operation of determining insertion, extraction, attachment, or detachment of the antenna 180 includes an operation of determining that the antenna 180 is extracted or attached when the signal is PLL locked.

According to an embodiment of the present invention, the operation of determining insertion, extraction, attachment, or detachment of the antenna 180 includes an operation of calculating an RSSI variation of a signal and an operation of determining that the antenna 180 is extracted or attached when an RSSI increase is greater than or equal to a set reference value.

According to an embodiment of the present invention, the operation of determining insertion, extraction, attachment, or detachment of the antenna 180 includes an operation of calculating a PER or BER variation of a signal and an operation of determining that the antenna 180 is extracted or attached when a PER or BER decrease is greater than or equal to a set reference value.

According to an embodiment of the present invention, the antenna 180 state determining method of an electronic device 101 further includes an operation of collecting location information on the electronic device 101 and an operation of setting reference values differently according to the location of the electronic device 101.

According to an embodiment of the present invention, the operation of collecting information on a signal includes an operation of collecting information on the signal in a set time interval.

According to an embodiment of the present invention, the antenna 180 state determining method of an electronic device 101 further includes an operation of displaying an object representing strength of a signal received via the antenna 180.

According to an embodiment of the present invention, the antenna 180 state determining method of an electronic device 101 further includes an operation of driving a corresponding application when the antenna 180 is determined as extracted or attached.

The above-described antenna 180 state determining method of an electronic device 101 according to an embodiment of the present invention may be implemented in a program executable in an electronic device. In addition, the program may be stored in various types of non-transitory computer-readable recording medium and used.

In detail, program codes for performing the above-described methods may be stored in various types of nonvolatile recording medium including a flash memory, a Read Only Memory (ROM), an Erasable Programmable ROM (EPROM), an Electronically Erasable and Programmable ROM (EEPROM), a hard disk, a removable disk, a memory card, a USB memory, and a Compact Disc ROM (CD-ROM).

According to an embodiment of the present invention, whether an antenna 180 is inserted or extracted can be determined via software without an additional hardware component operating as a switch. For example, a space for including such a hardware component can be omitted and costs associated with the component can be saved. In another example, malfunctions can be prevented that may occur due to deterioration of the hardware component from frequent use of the hardware component.

While embodiments of the present invention have been shown and described above, it will be understood by one of ordinary skill in the art that various changes in form and details may be made therein without departing from the scope and spirit of the present invention as defined by the following claims and their equivalents. The above-described embodiments of the present invention should be considered in a descriptive sense only and not for purposes of limitation. Therefore, the scope of the present invention is defined not by the detailed description of embodiments of the present invention but by the following claims and their equivalents, and all differences within the scope of the present invention will be construed as being included in the present invention.

What is claimed is:

1. An electronic device, comprising:
an antenna configured to be extractable or detachable;
an information collecting unit configured to collect information on a signal received via the antenna; and
a determination unit configured to determine insertion, extraction, attachment, or detachment of the antenna by using the collected information.

2. The electronic device according to claim 1, wherein the information collecting unit is further configured to collect at least one piece of information selected from whether the signal is Phased Locked Loop (PLL) locked, a Received Signal Strength Indicator (RSSI), a Packet Error Rate (PER), a Bit Error Rate (BER), and a combination thereof.

3. The electronic device according to claim 1, wherein the determination unit is further configured to determine that the antenna is extracted or attached when the signal is Phased Locked Loop (PLL) locked.

4. The electronic device according to claim 1, wherein the determination unit is further configured to determine that the antenna is extracted or attached when an increase in a Received Signal Strength Indicator (RSSI) of the signal is greater than or equal to a reference value.

5. The electronic device according to claim 1, wherein the determination unit determines that the antenna is extracted or attached when a Packet Error Rate (PER) or a Bit Error Rate (BER) decrease of the signal is greater than or equal to a reference value.

6. The electronic device according to claim 4, wherein the reference value is determined according to a location of the electronic device.

7. The electronic device according to claim 1, wherein the information collecting unit is further configured to collect information on the signal in a time interval.

8. The electronic device according to claim 1, further comprising a display configured to display an object representing strength of the signal received via the antenna.

9. The electronic device according to claim 1, further comprising an application driving unit configured to drive a corresponding application when the antenna is determined as extracted or attached.

10. An antenna state determining method of an electronic device, comprising:
collecting information on a signal received via an extractable or detachable antenna; and
determining insertion, extraction, attachment, or detachment of the antenna by using the collected information.

11. The method according to claim 10, wherein collecting information on the signal comprises collecting at least one piece of information selected from whether the signal is Phased Locked Loop (PLL) locked, a Received Signal Strength Indicator (RSSI), a Packet Error Rate (PER), a Bit Error Rate (BER), and a combination thereof.

12. The method according to claim 10, wherein determining insertion, extraction, attachment, or detachment of the antenna comprises determining that the antenna is extracted or attached when the signal is Phased Locked Loop (PLL) locked.

13. The method according to claim 10, wherein determining insertion, extraction, attachment, or detachment of the antenna comprises,
calculating a variation of an Received Signal Strength Indicator (RSSI) of the signal; and
determining that the antenna is extracted or attached when an increase in the RSSI of the signal is greater than or equal to a reference value.

14. The method according to claim 10, wherein determining insertion, extraction, attachment, or detachment of the antenna comprises,
calculating a variation of a Packet Error Rate (PER) or a Bit Error Rate (BER) of the signal; and
determining that the antenna is extracted or attached when a decrease in the PER or the BER of the signal is greater than or equal to a set reference value.

15. The method according to claim 13, further comprising:
collecting information on a location of the electronic device; and
setting the reference value according to the location of the electronic device.

16. The method according to claim 10, wherein collecting-information on the signal comprises collecting information on the signal in a time interval.

17. The method according to claim 10, further comprising displaying an object representing strength of the signal received via the antenna.

18. The method according to claim 10, further comprising driving a corresponding application when the antenna is determined as extracted or attached.

19. A non-transitory computer readable recording medium having a program recorded thereon, which, when executed by a computer, performs a method comprising:
collecting information on a signal received via an extractable or detachable antenna; and
determining insertion, extraction, attachment, or detachment of the antenna by using the collected information.

20. The non-transitory computer readable recording medium according to claim 19, wherein collecting information on the signal comprises collecting at least one piece of information selected from whether the signal is Phased Locked Loop (PLL) locked, a Received Signal Strength Indicator (RSSI), a Packet Error Rate (PER), a Bit Error Rate (BER), and a combination thereof.
